(19) United States
(12) Patent Application Publication
(10) Pub. No.: US 2007/0281424 A1
(43) Pub. Date: Dec. 6, 2007

(54) SEMICONDUCTOR DEVICE AND METHOD OF ITS FORMATION

(75) Inventors: Hyun-Su Kim, Gyeonggi-do (KR); Dae-Yong Kim, Gyeonggi-do (KR); Eun-Ji Jung, Gyeonggi-do (KR); Eun-Ok Lee, Incheon-gwangyeoksi (KR); Byung-Hee Kim, Seoul (KR); Jong-Ho Yun, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 11/750,699

(22) Filed: May 18, 2007

(30) Foreign Application Priority Data
May 19, 2006 (KR) 2006-45277

(51) Int. Cl. H01L 21/336

(52) U.S. Cl. 438/257

(57) ABSTRACT

In an embodiment a first silicon pattern and a second silicon pattern are formed on a substrate. The second silicon pattern has a lower top surface than the first silicon pattern. A first spacer covering a sidewall of the first silicon pattern is formed and a second spacer covering a sidewall of the second silicon pattern is formed. A silicide process is performed to silicidize the first silicon pattern and the second silicon pattern. Work functions of the first and second silicon patterns can be controlled and optimized by controlling the composition of the first and second silicon patterns.

### CROSS-REFERENCE TO RELATED APPLICATIONS

This U.S. non-provisional patent application claims priority under 35 U.S.C. § 119 of Korean Patent Application No. 2006-45277 filed on May 19, 2006, the entirety of which is hereby incorporated by reference.

### BACKGROUND

Embodiments of the present invention relate to a semiconductor device, such as one having an NMOS or PMOS transistor, and a method of its formation.

Typically, a CMOS transistor includes an NMOS transistor and a PMOS transistor. CMOS transistors are widely used due to its advantages directed to low operating voltage, high integration, and low electrical consumption.

As the operating speed of semiconductor devices increases, the operating speeds of both the NMOS transistor and the PMOS transistor also must increase. In order for the NMOS and PMOS transistors to have optimized operating features while operating in high speed, gate electrodes of the MNOS and PMOS transistors should have optimized work functions, respectively. In other words, the work function of the gate electrode of the NMOS transistor should be close to the silicon conduction-band edge energy level, and the work function of the gate electrode of the PMOS transistor should be close to the silicon valence-band edge energy level.

Conventionally, gate electrodes of NMOS and PMOS transistors have been made of doped polysilicon. In other words, the gate electrode of the NMOS transistor has been made of polysilicon doped with n-type impurities, and the gate electrode of the PMOS transistor has been made of polysilicon doped with p-type impurities. In this case, the work functions of the gate electrodes are close to the silicon conduction-band edge energy level and to the silicon valence-band edge energy level, respectively, so that both the NMOS and PMOS transistors may operate at high speed. However, when gate electrodes are made of polysilicon, problems such as polysilicon depletion and boron penetration may occur. The actual thickness of the gate insulating layer is increased due to the polysilicon depletion, which causes an effective gate voltage to decrease. Also, the threshold voltage of the transistor changes due to the boron penetration.

Therefore, methods of forming gate electrodes with metal group materials instead of polysilicon are suggested. A metal group material is highly conductive, and its use helps to avoid problems that may be caused by polysilicon depletion and boron penetration. However, metal gate electrodes cause degradation of the gate insulating layer due to metal ions, and because their work function is a fixed value, it is difficult to control the threshold voltage. Therefore, gate electrodes of NMOS and PMOS transistors using metal group materials cannot have optimized work functions. In order for the gate electrodes to have optimized work functions, each gate electrode should be formed with metal group materials different from each other. However, this complicates the manufacturing processes.

Recently, methods of forming gate electrodes with metal silicides are being introduced to form NMOS and PMOS transistors having improved operating features, and to overcome above problems caused by polysilicon gate electrodes and metal gate electrodes. However, NMOS and PMOS transistors with further improved operating features continue to be desired.

### SUMMARY OF EMBODIMENTS

Embodiments of the present invention are directed to a semiconductor device and method of its formation the same. In some embodiments, the method may comprise: preparing a substrate including a first region and a second region; forming a first silicon pattern in the first region, and forming a second silicon pattern in the second region, the second silicon pattern having a lower top surface than the first silicon pattern; forming a first spacer covering a sidewall of the first silicon pattern, and forming a second spacer covering a sidewall of the second silicon pattern; and performing a silicide process to silicidize the first silicon pattern and the second silicon pattern.

In other embodiments, the method may comprise: preparing a substrate including a first region and a second region; forming a silicon layer on the substrate, the silicon layer having a smaller thickness in the second region than in the first region; forming a sacrificial layer on the silicon layer; patterning the sacrificial layer and the silicon layer to form a first silicon pattern and a first sacrificial pattern in the first region, and to form a second silicon pattern and a second sacrificial pattern in the second region; forming a first preliminary spacer covering a sidewall of the first silicon pattern and the first sacrificial pattern, and forming a second preliminary spacer covering a sidewall of the second silicon pattern and the second sacrificial pattern; forming a mold insulating layer on the entire substrate; recessing the first preliminary spacer, the second preliminary spacer, and the mold insulating layer with an etch process to form a first spacer and a second spacer and to make the upper portion of the first silicon pattern protrude above the top surfaces of the first spacer and the recessed mold insulating layer; and performing a silicide process to silicidize the first silicon pattern and the second silicon pattern.

In still other embodiments, a device may comprise: a substrate including a first region and a second region; a first gate electrode in the first region, and a second gate electrode in the second region, the second gate electrode having a lower top surface than the first gate electrode; and a first spacer covering a sidewall of the first gate electrode, and a second spacer covering a sidewall of the second gate electrode, wherein the first gate electrode and the second gate electrode comprise a metal silicide, and the first gate electrode has a higher top surface than the first spacer, and the second gate electrode has a higher top surface than the second spacer.

### BRIEF DESCRIPTION OF THE DRAWINGS

FIG. 1 is a cross-sectional view of a semiconductor device according to some embodiments.

FIG. 2 is a cross-sectional view of a semiconductor device according to other embodiments.

FIGS. 3 to 10 are cross-sectional views to describe methods of forming a semiconductor device according to yet other embodiments.

FIGS. 11 to 13 are cross-sectional views to describe methods of forming a semiconductor device according to still other embodiments.

### DETAILED DESCRIPTION OF PREFERRED EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

(Structure of a Semiconductor Device)

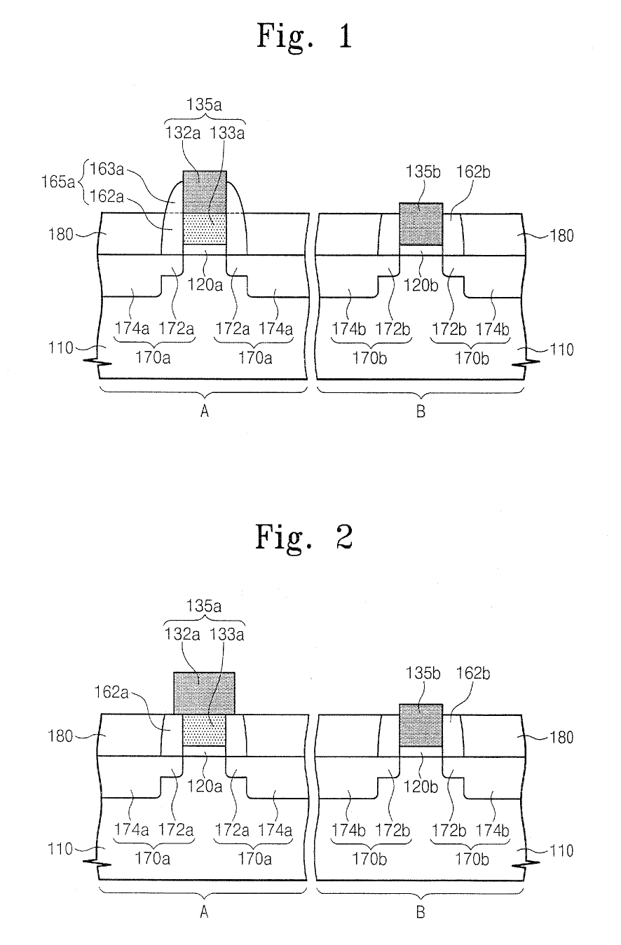

FIG. 1 is a cross-sectional view of a semiconductor device according to some embodiments. Substrate 110 includes a first region A and a second region B. The first region A and the second region B may be located in an active region defined by a device isolating region (not shown) disposed on the substrate 110. The active region may include a well formed on the substrate or a silicon layer formed on an insulating layer. One of the first and the second regions A and B may be an NMOS region that includes an NMOS transistor, and the other may be PMOS region that includes a PMOS transistor.

A first gate electrode 135a is disposed on the substrate 110 of the first region A, and a second gate electrode 135b is disposed on the substrate 110 of the second region B. The second gate electrode 135b may have a lower top surface than the first gate electrode 135a. A first gate insulating layer 120a is interposed between the first gate electrode 135a and the substrate 110, and a second gate insulating layer 120b is interposed between the second gate electrode 135b and the substrate 110.

The first gate electrode 135a may be made of a first metal silicide (hereinafter named 135a also), and the second gate electrode 135b may be made of a second metal silicide (hereinafter named 135b also). The first metal silicide 135a may include a bottom metal silicide 133a and a top metal silicide 132a. The first and the second metal silicides 135a and 135b may include the same metal element. Also, the first and the second metal silicides 135a and 135b may include silicon. The first metal silicide 135a and the second metal silicide 135b have different silicon concentrations compared to each other. The silicon concentration of the first metal silicide 135a is higher than that of the second metal silicide 135b. In other words, the metal concentration of the first metal silicide is higher than that of the second metal silicide. Also, the bottom metal silicide 133a and the top metal silicide 132a may have different silicon concentrations compared to each other. The silicon concentration of the bottom metal silicide 133a may be higher or equal to the silicon concentration of the top metal silicide 132a.

Having an influence by their proximity, a first and a second gate insulating layer 120a and 120b may increase or decrease the inherent work functions of the first and the second metal silicides 135a and 135b, respectively. This is due to an interfacial state between the gate insulating layers 120a and 120b and the gate electrodes 135a and 135b. The interfacial state is formed by the bonding of a specific element in the gate insulating layers 120a and 120b and the bonding of a silicon element in the gate electrodes 135a and 135b. This can change the work functions of the metal silicides 135a and 135b. Also, the work function can decrease as the density of the interfacial state decreases. The density of the interfacial state corresponds to the silicon concentration in the gate electrodes 135a and 135b. That is, as silicon concentration in the gate electrodes 135a and 135b increases, the density of the interfacial state increases. And as the silicon concentration in the gate electrodes 135a and 135b decreases, the density of the interfacial state decreases. Silicon concentration of the first metal silicide 135a is higher than the silicon concentration of the second metal silicide 135b. Therefore, a change of the inherent work function of the first metal silicide 135a is larger than a change of the inherent work function of the second metal silicide 135b.

Inherent work functions of the first and the second metal silicides 135a and 135b are values between the silicon conduction-band edge energy level (approximately, 4.01 eV) and the silicon valence-band edge energy level (approximately, 5.13 eV).

The first region A may be an NMOS region and the second region B may be a PMOS region, according to an embodiment. In this case, the work function of the first gate electrode 135a is closer to the silicon conduction-band edge energy level compared to the work function of the second gate electrode 135b. The work function of the second gate electrode 135b is closer to the silicon valence-band edge energy level compared to work function of the first gate electrode 135a. In other words, the work function of the first gate electrode 135a is smaller than the work function of the second gate electrode 135b.

For example, the metal silicides 135a and 135b may include nickel silicide (NiSi), cobalt silicide (CoSi₂), or platinum silicide PtSi₂, and the gate insulating layers 120a and 120b may include hafnium oxides, hafnium silicates, zirconium oxides, or zirconium silicates. An interfacial state is formed from bonding the silicon of the gate insulating layers 120a and 120b with zirconium and silicon of the metal silicides 135a and 135b. The interfacial state may decrease the work functions of the metal silicides 135a and 135b. Therefore, the decrease in the work function of the first gate electrode 135a having a relatively high silicon concentration is larger than the decrease in the work function of the second gate electrode 135b having a relatively low silicon concentration. In other words, the first gate electrode 135a may have a work function closer to the silicon conduction-band edge energy level, and the second gate electrode 135b may have a work function closer to the silicon valence-band edge energy level compared to the first gate electrode 135a. As a result, the NMOS transistor formed in the first region A and the PMOS transistor formed in the second region B may both have an optimized threshold voltage. The NMOS and PMOS transistors may then operate with an improved performance at a high speed.

In another embodiment, the first region A may be a PMOS region and the second region B may be an NMOS region. In this case, the work function of the first gate electrode 135a is closer to the silicon conduction-band edge energy level compared to the work function of the second gate electrode 135b. The work function of the second gate electrode 135b is closer to the silicon valence-band edge energy level compared to the work function of the first gate electrode 135b. The work function of the first gate electrode 135a is larger than the work function of the second gate electrode 135b.

For example, the metal silicides 135a and 135b may include tantalum silicide (TaSi₂) or molybden silicides (MOSi₂), and the gate insulating layers 120a and 120b may include aluminum oxide or aluminum silicates. An interfacial state is formed by bonding aluminum in the gate insulating layers 120a and 120b with silicon in the metal silicides 135a and 135b. The interfacial state may increase the work functions of the metal silicides 135a and 135b. Therefore, the increase of the work function of the first gate electrode 135a having a relatively high silicon concentration is larger than the increase of the work function of the second gate electrode 135b having a relatively low silicon concentration. In other words, the first gate electrode 135a may have a work function closer to the silicon valence-band edge energy level compared to the second gate electrode 135b. And the second gate electrode 135b may have a work function closer to the silicon conduction-band edge energy level compared to the first gate electrode 135a. As a result, the PMOS transistor formed in the first region A and the NMOS transistor formed in the second region B may both have an optimized threshold voltage.

Continuing with FIG. 1, a first and a second spacer 165a and 162b are disposed on opposite sides of the first and the second gate electrodes 135a and 135b, respectively. The sidewalls of the first gate electrode 135a are covered with the first spacer 165a, and the sidewalls of the second gate electrode 135b are covered with the second spacer 162b. The first gate electrode 135a has a higher top portion than the first spacer 165a. In other words, the first gate electrode 135a protrudes above the first spacer 165a, and the second gate electrode 135b protrudes above the second spacer 162b. Also, the first spacer 165a includes a bottom spacer 162a and a top spacer 163a. Sidewalls of a bottom metal silicide 133a may be covered with the bottom spacer 162a, and sidewalls of a top metal silicide 132a may be covered with the top spacer 163a.

The first and the second spacers 165a and 162b may be made of the same material. For example, the first and the second spacers may be made of silicon oxide, silicon nitride, or silicon oxynitride.

A first source/drain region 170a is disposed on a substrate 110 of the first region A located on opposite sides of the first gate electrode 135a. If the first region A is an NMOS region, the first source/drain region 170a may be doped with n-type impurities, and if the first region A is a PMOS region, the first source/drain region 170a may be doped with p-type impurities. The first source/drain region 170a may include a first low-concentration impurity region 172a and a first high-concentration impurity region 174a. The first low-concentration impurity region 172a is disposed between a channel region defined below the first gate electrode 135a and the first high-concentration impurity region 174a. In other words, the first source/drain region 170a may be a LDD structure or an extended source/drain structure.

A second source/drain region 170b is disposed on the substrate 110 of the second region B located on opposite sides of the second gate electrode 135b. If the second region B is a PMOS region, the second source/drain region 170b may be doped with p-type impurities, and if the second region B is an NMOS region, the second source/drain region 170b may be doped with n-type impurities. The second source/drain region 170b may include a second low-concentration region 172b and a second high-concentration impurity region 174b. The second low-concentration region 172b is disposed in a channel region defined below the second gate electrode 135b and the second high concentration impurity region 174b. In other words, the second low-concentration impurity region 172b is disposed below the second spacer 162b. The second source/drain region 170b may be a LDD structure or an extended source/drain structure.

The first and the second source/drain regions 170a and 170b may be doped with different types of impurities from each other.

A mold insulating layer 180 enclosing sidewalls of the first and the second gate electrodes 135a and 135b may be disposed on the substrate 110. Spacers 165a and 162b may be disposed between the gate electrodes 135a and 135b and the mold insulating layer 180. The mold insulating layer 180 may have a top surface at the same level as the top surfaces of the bottom spacer 162a and the second spacer 162b. The mold insulating layer 180 may be made of a material such as silicon oxide.

FIG. 2 is a cross-sectional view of a semiconductor substrate illustrating briefly a semiconductor device according to other embodiments.

Referring to FIG. 2, the configuration of the first gate electrode 135a with the first spacer 162a is a distinguishing feature of this embodiment. More specifically, the width of the upper portion of the metal silicide 132a is larger than the width of the lower portion of the metal silicide 133a. In other words, the upper portion of the metal silicide 132a may be extended above the first spacer 162a. The first spacer 162a may not include the top spacer 163a that is illustrated in FIG. 1. That is, the sidewalls of the bottom metal silicide 133a are covered with the first spacer 162a. An additional spacer covering the sidewalls of the upper portion of the metal silicide 132a may be further disposed.

(Method of Forming Semiconductor Device)

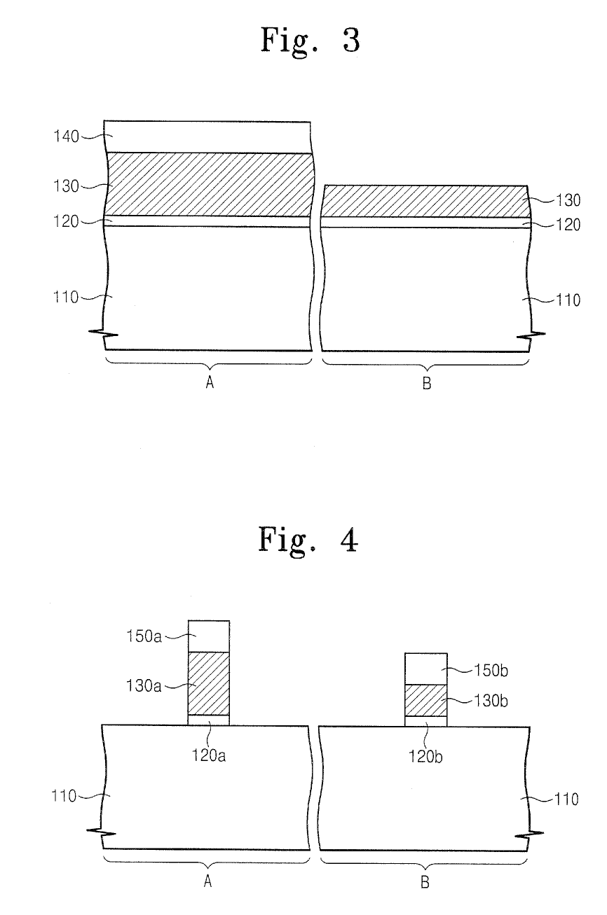

FIGS. 3 to 10 are cross-sectional views of a semiconductor device, such as the embodiments described above, to describe a method of forming the semiconductor device, according to still other embodiments.

Referring to FIG. 3, a substrate including a first region A and a second region B is prepared. One of the first and the second regions A and B is an NMOS region in which an NMOS transistor is formed, and the other is a PMOS region in which a PMOS transistor is formed. A single crystalline silicon substrate or a SOI substrate may be used for substrate 110. The first and the second regions A and B may be defined by forming a well in an active region. The active region is defined by a device isolating region (not shown). The well may not be formed if a SOI substrate having a completely isolated silicon layer (or a SOI layer) is used.

An insulating layer 120 is formed on a top surface of the substrate 110. The insulating layer 120 may be processed by a well-known thin film process such as a thermal oxidation process or a chemical vapor deposition (CVD) process. The insulating layer 120 may be made of silicon oxide, hafnium oxide, hafnium silicate, zirconium oxide, zirconium silicate, aluminum oxide, or aluminum silicate.

A silicon layer 130 having a smaller thickness in the second region B than in the first region A is formed on the insulating layer 120. The silicon layer 130 may be formed with polycrystalline silicon or amorphous silicon. Silicon layer 130 may be formed by forming a silicon layer having substantially equal thicknesses throughout the top surface of the substrate, then by etching a portion of the silicon layer of the second region. In doing this, a dry etching method may be used. Also, a mask pattern 140 covering the first region may be formed before performing the etch process. The mask pattern 140 may be used as a etch mask in the etch process. The thickness of the silicon layer 130 in the first region A and the second region B may be decided upon considering the thickness of the gate electrode formed in the following process.

Referring to FIG. 4, a sacrificial layer is formed on the silicon layer 130 after the mask pattern 140 is removed. The sacrificial layer may be processed by a well-known thin film process to be made of materials such as silicon oxide, silicon nitride, or silicon oxynitride. Subsequently, an etch process is performed to pattern the sacrificial layer, the silicon layer, and the insulating layer. From this, a first gate insulating layer 120a, a first silicon pattern 130a, and a first sacrificial pattern 150a are formed in the first region A. And a second gate insulating layer 120b, a second silicon pattern 130b, and a second sacrificial layer pattern 150b are formed in the second region B. In an alternative embodiment, the insulating layer 120 formed on the substrate 110 on opposite sides of the first and the second patterns 130a and 130b may not be etched. The first and the second sacrificial patterns 150a and 150b may be used as etch masks of the first and the second silicon patterns 130a and 130b.

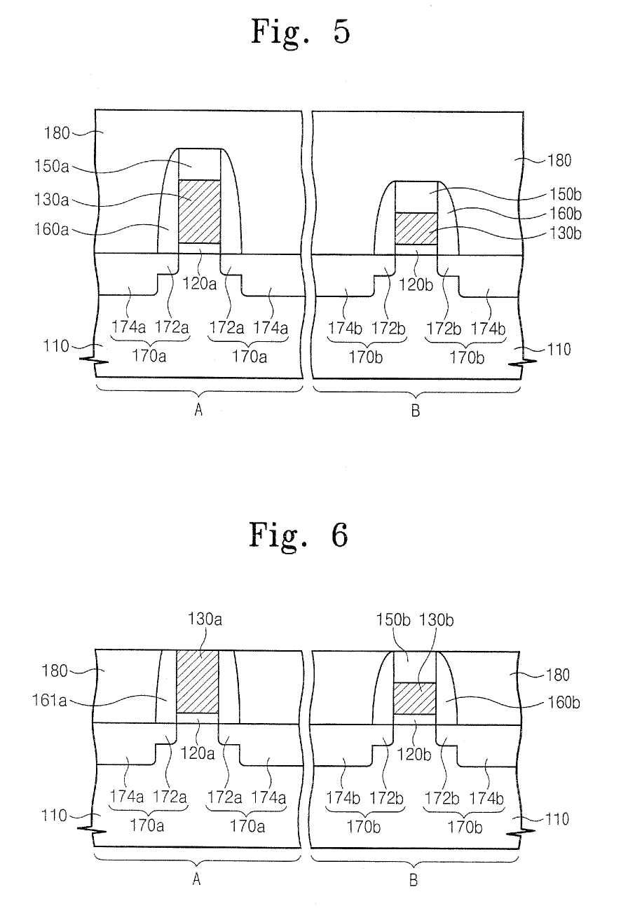

Referring to FIG. 5, a first low-concentration impurity region 172a is formed by injecting first impurity ions on substrate 110 in the first region A. Also, a second low-concentration impurity region 172b is formed by injecting second impurity ions on substrate 110 in the second region B. The first impurity ions and the second impurity ions may be different ion types. For example, the first impurity ions may be n-type and the second impurity ions may be p-type.

A first preliminary spacer 160a covering sidewalls of the first silicon pattern 130a and a second preliminary spacer 160b covering the second silicon pattern 130b are formed. The first preliminary spacer 160a and the second preliminary spacer 160b are formed by anisotropically etching the entire surface after a spacer insulating layer is formed on the entire surface of substrate (not shown). The spacer insulating layer may be silicon oxide, silicon nitride, or silicon oxynitride.

Subsequently, a first high-concentration impurity region 174a is formed by injecting first impurity ions into the substrate 110 in the first region A. Also, a second high-concentration impurity region 174b is formed by injecting second impurity ions into the substrate 110 in the second region B. The first and the second preliminary spacers 160a and 160b function as ion injection masks, therefore first and second low-concentration impurity regions 172a and 172b remain under the first and the second preliminary spacers 160a and 160b.

The first low-concentration impurity region 172a and the first high-concentration impurity region 174a constitute the first source/drain region 170a, and the second low-concentration impurity region 172b and the second high-concentration impurity region 174b constitute the second source/drain region 170b.

A mold insulating layer 180 may be formed on the entire surface of the substrate 10. The mold insulating layer 180 may be made of silicon oxide or other similar materials, for example. A silicide process may be performed before forming the mold insulating layer 180 to form a silicide layer (not shown) on the first and the second high-concentration impurity regions 174a and 174b.

Referring to FIG. 6, a first etch process may be performed to eliminate the first sacrificial layer pattern 150a and to expose the first silicon layer 130a. Also, the first preliminary spacer 160a and the mold insulating layer 180 may be recessed. The second sacrificial pattern 150b may also be exposed. The top surfaces of the recessed first preliminary spacer 161a and the mold insulating layer 180 may be at the same level as the top surface of the first silicon pattern 130a. The first etch process may include planarization and the planarization may include a CMP process or an etch back process.

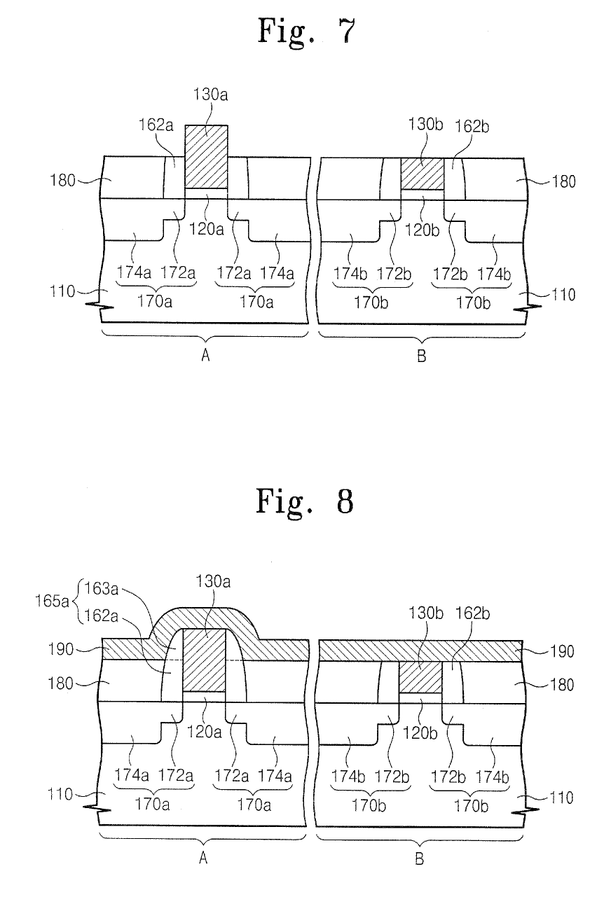

Referring to FIG. 7, a second etch process may be 0performed to eliminate the second sacrificial layer pattern 150b and to expose the second silicon pattern 130b. The recessed first preliminary spacer 161a is recessed again to become a bottom spacer 162a, and the second preliminary spacer 160b is recessed to become a second spacer 162b. The mold insulating layer 180 is also recessed. The top surfaces of the bottom spacer 162a, the second spacer 162b, and the mold insulating layer 180 may be at the same level with the top surface of the second silicon pattern 130b. An upper portion of the first silicon pattern 130a now protrudes above the bottom spacer 162a and the mold insulating layer 180. The second etch process may include dry etch process.

The first and the second etch processes may also be performed by a single sequential etch process. For example, the first etch process and the second etch process may be completed by performing a single dry etch process. Also, in the first and the second etch processes, an abrasive and/or an etch gas may be used to selectively etch the first and the second sacrificial patterns 150a and 150b and the first and the second preliminary spacers 160a and 160b with respect to the first and the second silicon patterns 130a and 130b.

Referring to FIG. 8, a top spacer 163a is formed to cover sidewalls of the protruded upper portion of the first silicon pattern 130a. The top spacer 163a may be formed by forming a spacer insulating layer (not shown) conformally on the substrate and then anisotropically etching the spacer insulating layer. The spacer insulating layer may be silicon oxide, silicon nitride, or silicon oxynitride. The bottom spacer 162a and the top spacer 163a constitute a first spacer 165a.

A metal layer 190 is then formed on the substrate having the exposed first silicon pattern 130a and the exposed second silicon pattern 130b. The metal layer 190 may be nickel, cobalt, platinum, tantalum, molybdenum, etc., formed by a well-known thin film process.

A selection of a metal material for the metal layer 190 may be decided upon by considering a relation between the metal silicide and the gate insulating layers 120a and 120b formed in the sequential process. For example, if the gate insulating layers 120a and 120b are made of hafnium oxides, hafnium silicates, zirconium oxides, or zirconium silicates, then the metal layer 190 may be made of nickel, cobalt, or platinum. Also, if the gate insulating layers 120a and 120b are made of aluminum oxide or an aluminum silicate layer, then the metal layer 190 may be made of tantalum or molybdenum.

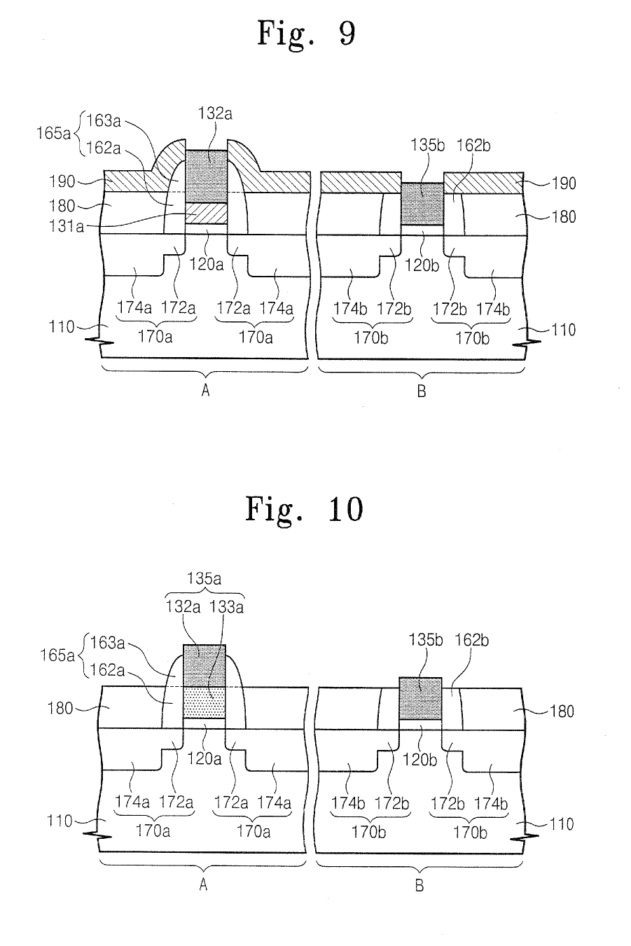

Referring to FIG. 9, a first silicide process is performed to silicidize the first silicon pattern 130a and the second silicon pattern 130b. The first silicide process may include a rapid thermal process. Only a portion of the metal layer 190 may react with the first and second silicon patterns 130a and 130b, leaving a remaining non-reactive metal layer 190.

Thus, the first silicon pattern 130a is transformed into a bottom silicon pattern 131a and a top metal silicide 132a, and the second silicon pattern 130b may all be transformed into a second metal silicide 135b. The top metal silicide 132a may protrude above the first spacer 165a, and the second metal silicide 135b may protrude above the second spacer 162b.

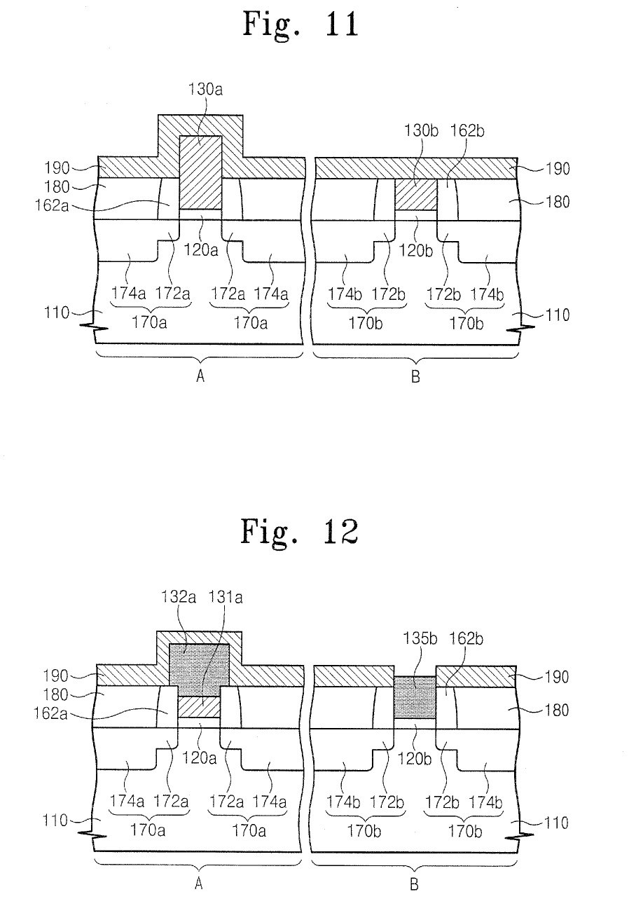

Referring to FIG. 10, after the non-reactive metal layer 190 is eliminated, a second silicide process may be performed to silicidize the bottom silicon pattern. The second silicide process may also include a rapid thermal process. Metal material included in the top metal silicide 132a may be diffused to the bottom silicon pattern 131a by the second silicide process. As a result, the bottom silicon pattern 131a reacts to the diffused metal material to be transformed into a bottom metal silicide 133a. The thickness of the top metal silicide 132a may be decreased. In other words, the thickness of the bottom metal silicide 133a may be thicker than the thickness of the bottom silicon pattern 131a. Also, the silicon concentration of the bottom metal silicide 133a may be higher than the silicon concentration of the top metal silicide 132a. The bottom metal silicide 133a and the top metal silicide 132a constitute a first metal silicide 135a.

As described above, the first and the second silicide processes form the first and the second metal silicides 135a and 135b having different silicon concentrations from each other. Two silicide processes are performed in the present embodiments; however, the second silicide process may be omitted. In other words, because the thicknesses of the first silicon pattern 130a and the second silicon pattern 130b are different from each other, the first and the second metal silicides 135a and 135b may have different silicon concentrations by performing only a first silicide process.

The first metal silicide 135a may become a first gate electrode having a relatively higher silicon concentration at the boundary with the first gate insulating layer 120a. The second metal silicide 135b may become a second gate electrode having a relatively lower silicon concentration at the boundary with the second gate insulating layer 120b. As a result, gate electrodes having different work functions are formed.

To summarize, conventional methods include forming a silicon pattern having a level top surface and a spacer covering the silicon pattern in first and second regions. Then the silicon pattern in the second region is etched back to form a silicon pattern having a low top surface. According to the conventional art, the etch back speed of the silicon pattern may vary according to the location on the substrate. Therefore, the silicon pattern having a low top surface cannot be formed level. Also, when a metal layer is formed on the silicon pattern, the metal layer may not be formed properly on the silicon pattern because the top surface of the etched back silicon pattern is lower than the spacer of its sidewalls. These problems may increase as design rule decreases.

However, according to embodiments of the present invention, silicon layers having different thicknesses corresponding to regions on the substrate are formed before the silicon pattern in formed. A silicon layer is patterned to have a higher top surface in a first region. A silicon pattern having a low top surface is formed in a second region. In other words, the silicon pattern having a low top surface may be formed level no matter where it is formed on the substrate. Also, a metal layer may be formed having a uniform thickness on the silicon pattern while the silicon pattern is protruded above its spacers. Thus, operational characteristics of NMOS and PMOS transistors may be improved.

FIGS. 11 to 13 are cross-sectional views of a semiconductor substrate to describe methods of forming a semiconductor device according to still other embodiments.

Referring to FIG. 11, the top spacer in FIG. 8 that covered the protruded top sidewall of the first silicon pattern 130a is not formed, contrary to the above explained embodiments. Therefore, the bottom spacer 162a becomes the first spacer.

A metal layer 190 is formed on the substrate having the exposed first silicon pattern 130a and the exposed second silicon pattern 130b. The metal layer 190 is in contact with the protruded top sidewall of the first silicon pattern 130a. The metal layer 190 may be formed by the same method as explained above.

Referring to FIG. 12, a first silicide process is performed to silicidize the first silicon pattern 130a and the second silicon pattern 130b. The first silicide process may include a rapid thermal process. The first silicon pattern 130a is transformed into a bottom silicon pattern 131a and a top metal silicide 132a by the first silicide process. The second silicon pattern 130b may all be transformed into the second metal silicide 135b. The top metal silicide 132a may extend laterally onto the first spacer 162a to have a larger width than the bottom silicon pattern 131a. The second metal silicide 135b may protrude above the second spacer 162b.

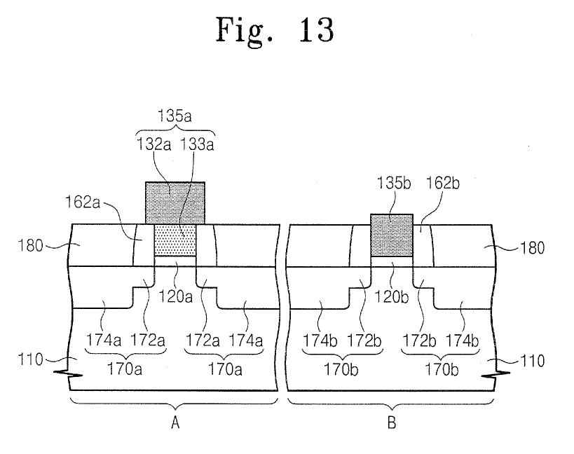

Referring to FIG. 13, a second silicide process may be performed after eliminating the metal layer 190 to silicidize the bottom silicon pattern 131a. The second silicide process may include a rapid thermal process. By the second silicide process, the metallic material included in the top metal silicide 132a is diffused to the bottom silicon pattern 131a. The bottom silicon pattern 131a reacts to the diffused metallic material to be transformed into the bottom metal silicide 133a. The thickness of the top metal silicide 132a may decrease. In other words, the thickness of the bottom metal silicide 133a may be thicker than the thickness of the bottom silicon pattern 131a. Also, the silicon concentration of the bottom metal silicide 133a may be larger than the silicon concentration of the top metal silicide 132a. The bottom metal silicide 133a and the top metal silicide 132a constitute a first metal silicide 135a.

Although not shown, a spacer covering the sidewall of the top metal silicide 132a may further be formed.

Although the present invention has been described in connection with embodiments illustrated in the accompanying drawings, it is not limited thereto. It will be apparent to those skilled in the art that various substitutions, modifications, and changes may be made without departing from the scope and spirit of the invention.

According to embodiments, despite design rule decreases due to a scaling down of semiconductor devices, metal silicide gate electrodes may be uniformly formed.

According to embodiments, metal silicide gate electrodes having top surfaces of different levels may be uniformly formed.

According to embodiments, metal silicide gate electrodes having top surfaces of different levels may be uniformly formed.

Therefore, operational characteristics of semiconductor devices having NMOS and PMOS transistors may be improved.

What is claimed is:

1. A method of forming a semiconductor device comprising:
forming a first silicon pattern in a first region of a substrate and forming a second silicon pattern in a second region of the substrate, the second silicon pattern having a lower top surface than the first silicon pattern;
forming a first spacer covering a sidewall of the first silicon pattern, and forming a second spacer covering a sidewall of the second silicon pattern; and
performing a silicide process to silicidize the first silicon pattern and the second silicon pattern.

2. The method of claim 1, wherein forming the first silicon pattern and the second silicon pattern comprises:
forming a silicon layer on the substrate, the silicon layer having a smaller thickness in the second region than in the first region;
forming a sacrificial layer on the silicon layer; and
patterning the sacrificial layer and the silicon layer,
wherein the first silicon pattern and a first sacrificial pattern are formed in the first region, and the second silicon pattern and a second sacrificial pattern are formed in the second region.

3. The method of claim 2, wherein the sacrificial layer, the first spacer, and the second spacer comprise materials having an etch selectivity with respect to the silicon layer.

4. The method of claim 2, wherein forming the first spacer and the second spacer comprises:
forming a first preliminary spacer covering the sidewall of the first silicon pattern and the first sacrificial pattern, and forming a second preliminary spacer covering the sidewall of the second silicon pattern and the second sacrificial pattern;
forming a mold insulating layer on the substrate; and
performing an etch process to recess the first preliminary spacer, the second preliminary spacer, and the mold insulating layer to the top surface of the second silicon pattern,
wherein the upper portion of the top first silicon pattern protrudes above the top surfaces of the recessed first preliminary spacer and the recessed mold insulating layer.

5. The method of claim 4, wherein the etch process comprises:
a first process to expose the first silicon pattern; and
a second process to expose the second silicon pattern,
wherein the first process comprises a planarization process, and the second process comprises a dry etch process.

6. The method of claim 4, further comprising:
forming a top spacer on the recessed first preliminary spacer, the top spacer covering a protruded top sidewall of the first silicon pattern.

7. The method of claim 6, wherein the silicide process comprises:
a thin film process in which a metal layer is formed on the protruded first silicon pattern and the exposed second silicon pattern; and
a rapid thermal process in which the metal layer reacts with the first silicon pattern and the second silicon pattern.

8. The method of claim 1, wherein the silicide process comprises:
a first silicide process to transform the first silicon pattern into a bottom silicon pattern and a top metal silicide, and to transform the second silicon pattern into a second metal silicide; and
a second silicide process to transform the bottom silicon pattern into a bottom metal silicide.

9. The method of claim 8, wherein the thickness of the top metal silicide is decreased by the second silicide process.

10. The method of claim 8, wherein the bottom metal silicide is formed by performing a rapid thermal process to diffuse metallic material included in the top metal silicide to the bottom silicon pattern.

11. A method of forming a semiconductor device comprising:
forming a silicon layer on the substrate, the silicon layer having a smaller thickness in a second region than in a first region;
forming a sacrificial layer on the silicon layer;
patterning the sacrificial layer and the silicon layer to form a first silicon pattern and a first sacrificial pattern in the first region, and to form a second silicon pattern and a second sacrificial pattern in the second region;
forming a first preliminary spacer covering a sidewall of the first silicon pattern and the first sacrificial pattern, and forming a second preliminary spacer covering a sidewall of the second silicon pattern and the second sacrificial pattern;
forming a mold insulating layer on the substrate;
recessing the first preliminary spacer, the second preliminary spacer, and the mold insulating layer by an etch process to form a first spacer and a second spacer and to make an upper portion of the first silicon pattern protrude above the top surfaces of the first spacer and the recessed mold insulating layer; and
performing a silicide process to silicidize the first silicon pattern and the second silicon pattern.

12. The method of claim 11, wherein the etch process comprises:
a first process to expose the first silicon pattern; and
a second process to expose the second silicon pattern,
wherein the first process comprises a planarization process, and the second process comprises a dry etch process.

13. The method of claim 11, further comprising:
forming a top spacer on the first spacer, the top spacer covering the protruded sidewall of the first silicon pattern.

14. The method of claim 11, wherein the silicide process comprises:
a first silicide process to transform the first silicon pattern into a bottom silicon pattern and a top metal silicide, and to transform the second silicon pattern into a second metal silicide; and
a second silicide process to transform the bottom silicon pattern into a bottom metal silicide.

15. A semiconductor device comprising:
a substrate including a first region and a second region;
a first gate electrode in the first region, and a second gate electrode in the second region, the second gate electrode having a lower top surface than the first gate electrode; and
a first spacer covering a sidewall of the first gate electrode, and a second spacer covering a sidewall of the second gate electrode,
wherein the first gate electrode and the second gate electrode comprise a metal silicide, and
the first gate electrode has a higher top surface than the first spacer, and the second gate electrode has a higher top surface than the second spacer.

16. The semiconductor device of claim 15, wherein the first gate electrode comprises a first metal silicide, and the second gate electrode comprises a second metal silicide; and
wherein a silicon concentration of the first metal silicide is higher than a silicon concentration of the second metal silicide.

17. The semiconductor device of claim 16, wherein the first metal silicide comprises a bottom metal silicide and a top metal silicide; and
wherein a silicon concentration of the bottom metal silicide is higher than or equal to a silicon concentration of the top metal silicide.

18. The semiconductor device of claim 17, wherein the first spacer comprises a bottom spacer covering a sidewall of the bottom metal silicide; and
a top spacer covering a sidewall of the top metal silicide.

19. The semiconductor device of claim 17, wherein the top metal silicide has a larger width than the bottom metal silicide.

20. The semiconductor device of claim 19, wherein the first spacer covers a sidewall of the bottom metal silicide and the top metal silicide extends over the first spacer.

21. The semiconductor device of claim 15 further comprising:
a first gate insulating layer interposed between the first gate electrode and the substrate and a second gate insulating layer interposed between the second gate electrode and the substrate,
wherein a silicon concentration at the boundary between the first gate insulating layer and the first gate electrode is higher than at the boundary between the second gate insulating layer and the second gate electrode.

22. The semiconductor device of claim 15, wherein an NMOS transistor is in the first region, and a PMOS transistor is in the second region; and
wherein the first gate electrode has a lower work function than the second gate electrode.

23. The semiconductor device of claim 15, wherein a PMOS transistor is in the first region, and an NMOS transistor is in the second region; and
wherein the first gate electrode has a higher work function than the second gate electrode.
